(19) United States
(12) Patent Application Publication
(10) Pub. No.: US 2018/0226303 A1
(43) Pub. Date: Aug. 9, 2018

(54) METHOD OF MANUFACTURING SEMICONDUCTOR DEVICE

(71) Applicant: SAMSUNG ELECTRONICS CO., LTD., SUWON-SI (KR)

(72) Inventors: HYOSIG WON, SUWON-SI (KR); Sang-Kyu Oh, GWACHEON-SI (KR); Sungmin Oh, YONGIN-SI (KR); Kwangok Jeong, HWASEONG-GI (KR)

(21) Appl. No.: 15/856,444

(22) Filed: Dec. 28, 2017

(30) Foreign Application Priority Data
Dec. 29, 2016 (KR) 10-2016-0182668
Aug. 24, 2017 (KR) 10-2017-0107481

(51) Int. Cl. H01L 21/66; H01L 21/8238; G01N 23/2251; G01R 31/26

(52) U.S. Cl. CPC H01L 22/10; H01L 21/8238; G01R 31/2644; G01N 23/2251; H01L 22/30

(57) ABSTRACT

A method of manufacturing a semiconductor device includes forming transistors in a cell region of a test wafer, forming a first test pattern on a first test cell in the cell region, the first test pattern being electrically connected to the transistors, and scanning the first test pattern using an electron beam. Forming the transistors in the cell region includes patterning an upper portion of the test wafer to form active patterns, forming source/drain regions on the active patterns, forming gate electrodes extending across the active patterns, forming active contacts coupled to the source/drain regions, and forming gate contacts coupled to the gate electrodes.

### CROSS-REFERENCE TO RELATED APPLICATIONS

This U.S. nonprovisional patent application claims priority under 35 U.S.C. § 119 to Korean Patent Application No. 10-2016-0182668, filed on Dec. 29, 2016, and Korean Patent Application No. 10-2017-0107481, filed on Aug. 24, 2017, the disclosures of which are incorporated by reference herein in their entireties.

### TECHNICAL FIELD

Exemplary embodiments of the present inventive concept relate to a method of manufacturing a semiconductor device, and more particularly, to a method of detecting process defects of a semiconductor device and a method of manufacturing a semiconductor device including the same.

### DISCUSSION OF THE RELATED ART

A semiconductor device is a widely used component in the electronic industry due to its small size, multifunctional capabilities, and low fabrication cost. A semiconductor device may be categorized as one of a semiconductor memory device that stores logic data, a semiconductor logic device that processes operations of logic data, and a hybrid semiconductor device having both memory and logic elements. As the use of semiconductor devices in the electronic industry continues to increase, there is a need for semiconductor devices having high reliability, high speed, and multifunctional capabilities. As semiconductor devices are being manufactured to meet these needs, semiconductor devices are becoming more complicated and highly integrated.

### SUMMARY

Exemplary embodiments of the present inventive concept provide a method of manufacturing a semiconductor device having improved reliability as a result of an improved process of detecting process defects.

According to exemplary embodiments of the present inventive concept, a method of manufacturing a semiconductor includes forming a plurality of transistors in a cell region of a test wafer, forming a first test pattern on a first test cell in the cell region of the test wafer, in which the first test pattern is electrically connected to the transistors, and scanning the first test pattern using an electron beam. Forming the transistors in the cell region includes forming a plurality of active patterns by patterning an upper portion of the test wafer, forming a plurality of source/drain regions on the active patterns, forming a plurality of gate electrodes extending across the active patterns, forming a plurality of active contacts coupled to the source/drain regions, and forming a plurality of gate contacts coupled to the gate electrodes.

According to exemplary embodiments of the present inventive concept, a method of manufacturing a semiconductor includes performing an electron beam inspection process on a cell region of a test wafer. The cell region of the test wafer includes a plurality of first active patterns, a plurality of second active patterns, a device isolation layer defining the first and second active patterns, in which upper portions of the first and second active patterns vertically protrude beyond the device isolation layer, a plurality of gate electrodes extending across the first and second active patterns, and a plurality of test patterns electrically connected to at least one of the first and second active patterns and the gate electrodes. The first active patterns and the gate electrodes constitute a plurality of p-channel metal-oxide field-effect (PMOS) transistors, and the second active patterns and the gate electrodes constitute a plurality of n-channel metal-oxide field-effect (NMOS) transistors.

According to exemplary embodiments of the present inventive concept, a method of manufacturing a semiconductor includes forming a plurality of logic transistors on a first logic cell of a test wafer, forming a first test pattern on the first logic cell of the test wafer, in which the first test pattern is electrically connected to the logic transistors, and scanning the first test pattern using an electron beam. The first logic cell includes a p-channel metal-oxide field-effect (PMOSFET) region, and an n-channel metal-oxide field-effect (NMOSFET) region. The logic transistors include a plurality of first active patterns in the PMOSFET region and extending in a first direction, a plurality of second active patterns in the NMOSFET region and extending in the first direction, and a plurality of gate electrodes extending in a second direction crossing the first direction and extending across the first and second active patterns.

According to exemplary embodiments of the inventive concept, a method of manufacturing a semiconductor device includes forming a plurality of first active patterns in a cell region of a test wafer, forming a plurality of second active patterns in the cell region, forming a device isolation layer defining the first and second active patterns, in which upper portions of the first and second active patterns vertically protrude beyond the device isolation layer, forming a plurality of gate electrodes extending across the first and second active patterns, forming a plurality of test patterns electrically connected to at least one of the first and second active patterns and the gate electrodes, in which the first active patterns and the gate electrodes constitute a plurality of p-channel metal-oxide field-effect (PMOS) transistors, and the second active patterns and the gate electrodes constitute a plurality of n-channel metal-oxide field-effect (NMOS) transistors, irradiating an electron beam onto the test patterns, and detecting at least one process defect by scanning electrons emitted from the test patterns in response to irradiating the electron beam onto the test patterns.

### BRIEF DESCRIPTION OF THE DRAWINGS

The above and other features of the present inventive concept will become more apparent by describing in detail exemplary embodiments thereof with reference to the accompanying drawings, in which:

FIG. 1 illustrates a flowchart describing a method of detecting process defects of a semiconductor device and manufacturing a semiconductor device according to exemplary embodiments of the present inventive concept.

FIG. 2 illustrates a plan view showing a wafer on which transistors are formed according to exemplary embodiments of the present inventive concept.

FIGS. 3, 6, and 9 illustrate a cell region in one chip of FIG. 2, and show a method of detecting process defects of a semiconductor device, according to exemplary embodiments of the inventive concept.

FIG. 4 illustrates an enlarged plan view showing section M of FIG. 3 according to an exemplary embodiment of the inventive concept.

FIGS. 5A, 5B, and 5C illustrate cross-sectional views respectively taken along lines A-A′, B-B′, and C-C′ of FIG. 4 according to exemplary embodiments of the inventive concept.

FIG. 7 illustrates an enlarged plan view showing section M of FIG. 6 according to an exemplary embodiment of the inventive concept.

FIGS. 8A, 8B, and 8C illustrate cross-sectional views respectively taken along lines A-A′, B-B′, and C-C′ of FIG. 7 according to exemplary embodiments of the inventive concept.

FIG. 10 illustrates a simplified cross-sectional view showing an electron beam scanning a first test cell of FIG. 9 according to an exemplary embodiment of the inventive concept.

FIGS. 11 and 13 illustrate enlarged plan views respectively showing section M of FIG. 3 and section M of FIG. 7, and show memory cells according to exemplary embodiments of the present inventive concept.

FIGS. 12A, 12B, and 12C illustrate cross-sectional views respectively taken along lines A-A′, B-B′, and C-C′ of FIG. 11 according to exemplary embodiments of the inventive concept.

FIGS. 14A, 14B, and 14C illustrate cross-sectional views respectively taken along lines A-A′, B-B′, and C-C′ of FIG. 13 according to exemplary embodiments of the inventive concept.

FIG. 15 illustrates a plan view of test patterns formed in a cell region in one chip of FIG. 2, and show a method of detecting process defects of a semiconductor device, according to exemplary embodiments of the present inventive concept.

FIG. 16 illustrates a plan view of test patterns formed in a cell region in one chip of FIG. 2, and show a method of detecting process defects of a semiconductor device, according to exemplary embodiments of the present inventive concept.

FIG. 17 illustrates a plan view of test patterns formed in a cell region in one chip of FIG. 2, and show a method of detecting process defects of a semiconductor device, according to exemplary embodiments of the present inventive concept.

FIG. 18 illustrates a flowchart describing a method of detecting process defects of a semiconductor device, and show a method of manufacturing a semiconductor device, according to exemplary embodiments of the present inventive concept.

FIG. 19 illustrates a plan view showing a test wafer selected from a wafer set that has undergone a first process according to an exemplary embodiment of the inventive concept.

FIGS. 20, 21, and 24 illustrate plan views showing a cell region in one chip according to an exemplary embodiment of the inventive concept.

FIG. 22 illustrates an enlarged plan view showing section N of FIG. 21 according to an exemplary embodiment of the inventive concept.

FIGS. 23A, 23B, and 23C are cross-sectional views respectively taken along lines A-A′, B-B′, and C-C′ of FIG. 22 according to exemplary embodiments of the inventive concept.

### DETAILED DESCRIPTION OF THE EXEMPLARY EMBODIMENTS

Exemplary embodiments of the present inventive concept will be described more fully hereinafter with reference to the accompanying drawings. Like reference numerals may refer to like elements throughout the accompanying drawings.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be further understood that when a component is referred to as being ‘on’, ‘connected to’, ‘coupled to’, or ‘adjacent to’ another component, it can be directly on, connected to, coupled to, or adjacent to the other component, or intervening components may also be present. It will also be understood that when a component is referred to as being ‘between’ two components, it can be the only component between the two components, or one or more intervening components may also be present.

It will be understood that the terms “first,” “second,” “third,” etc. are used herein to distinguish one element from another, and the elements are not limited by these terms. Thus, a “first” element in an exemplary embodiment may be described as a “second” element in another exemplary embodiment.

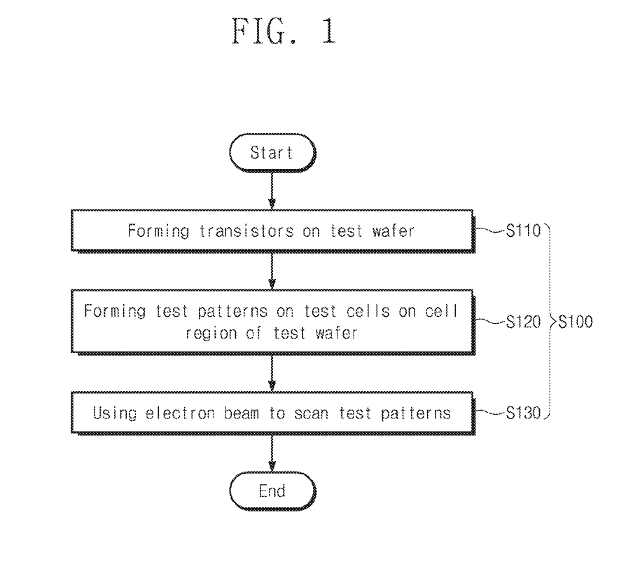

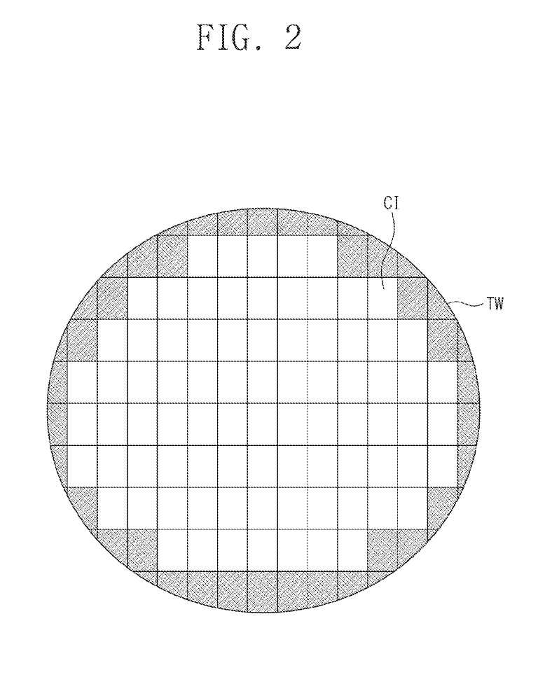

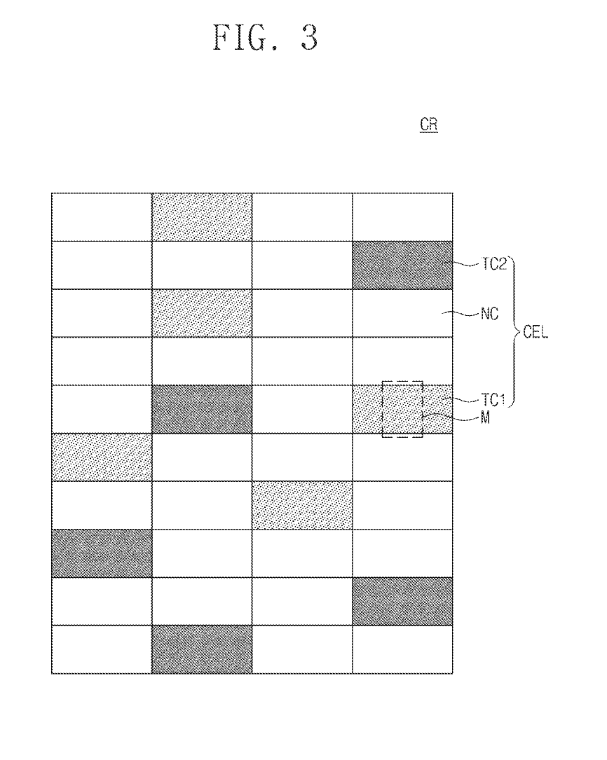

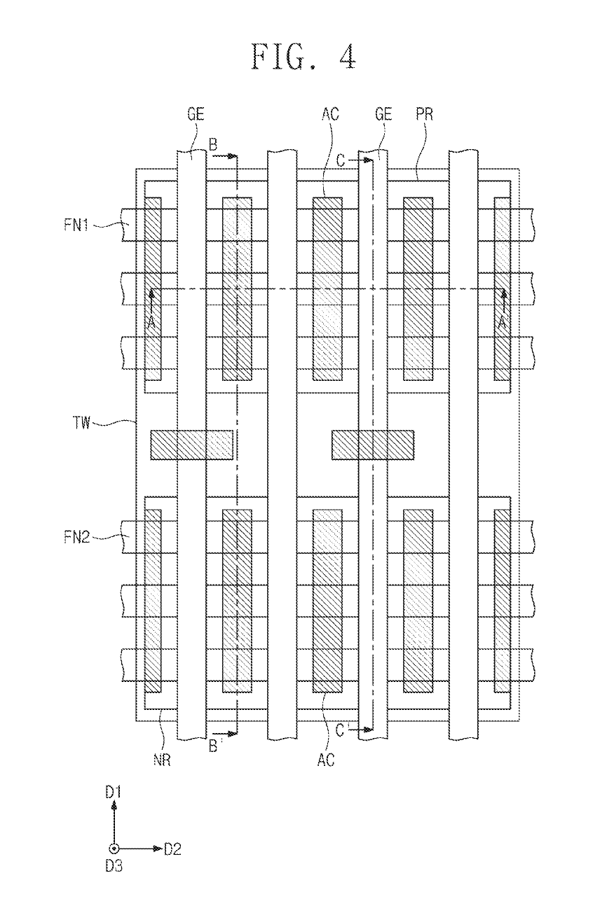

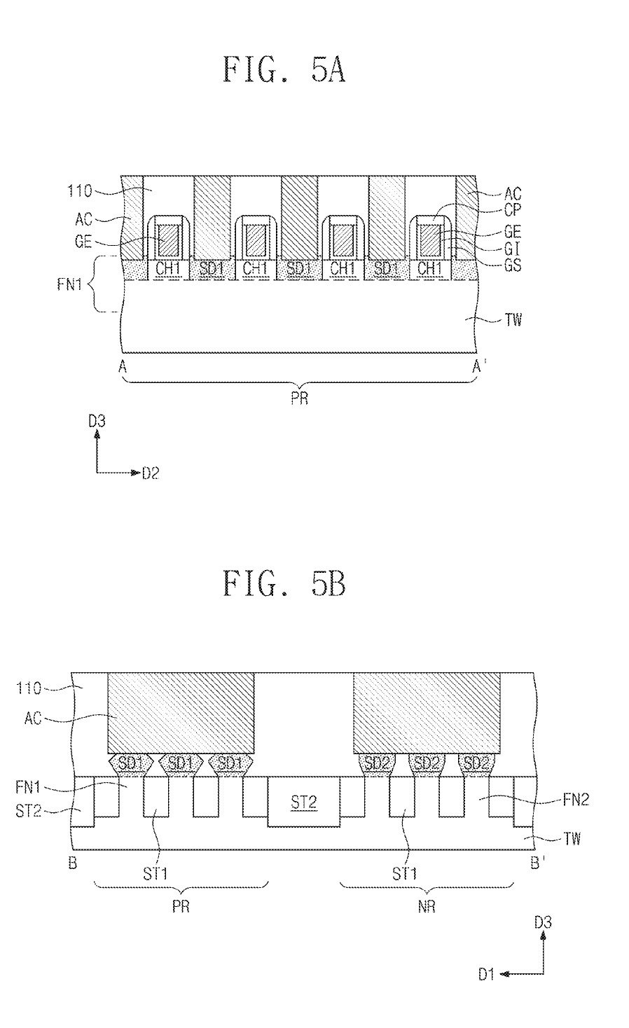

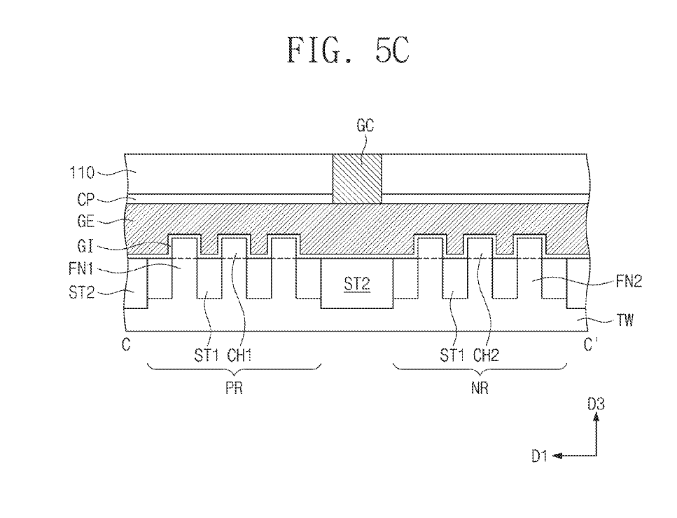

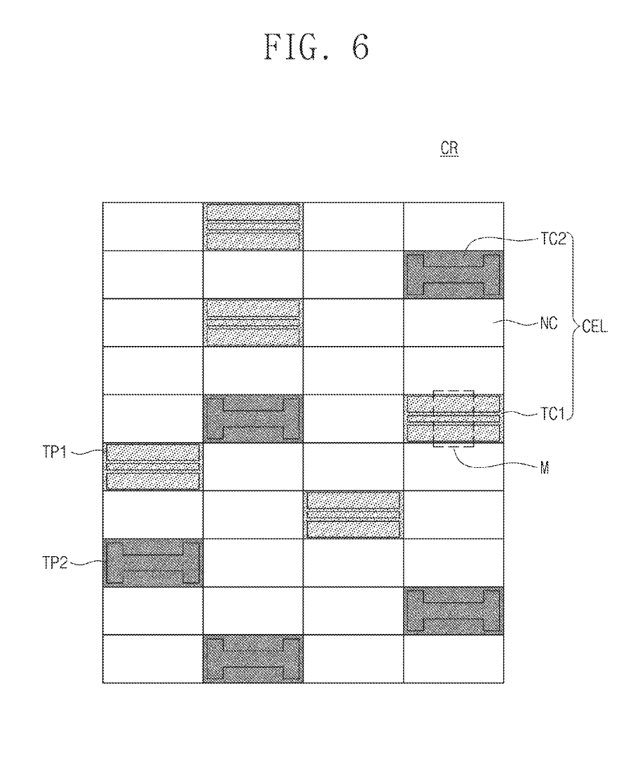

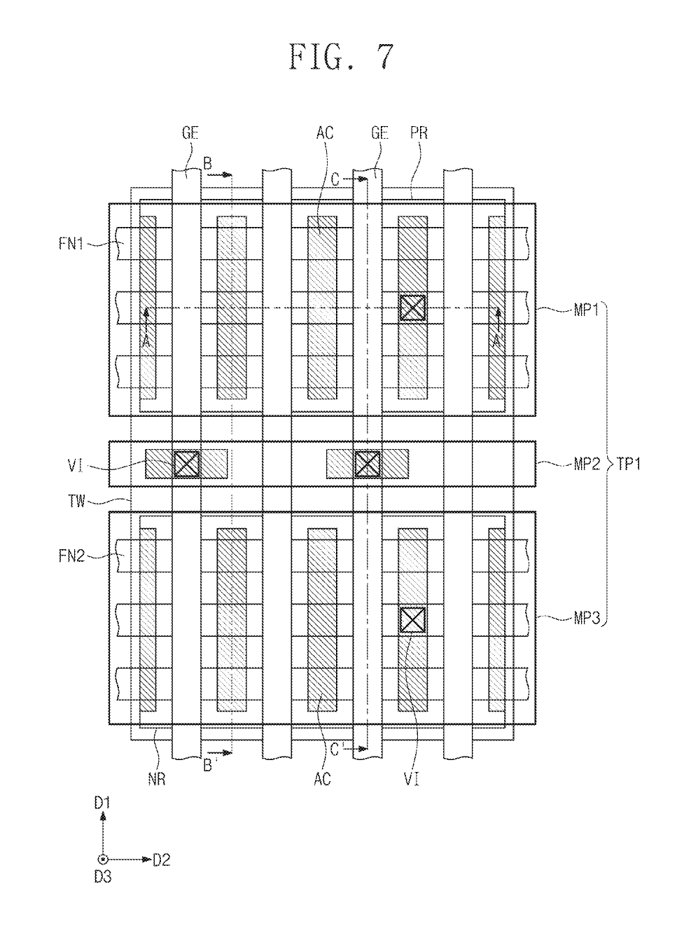

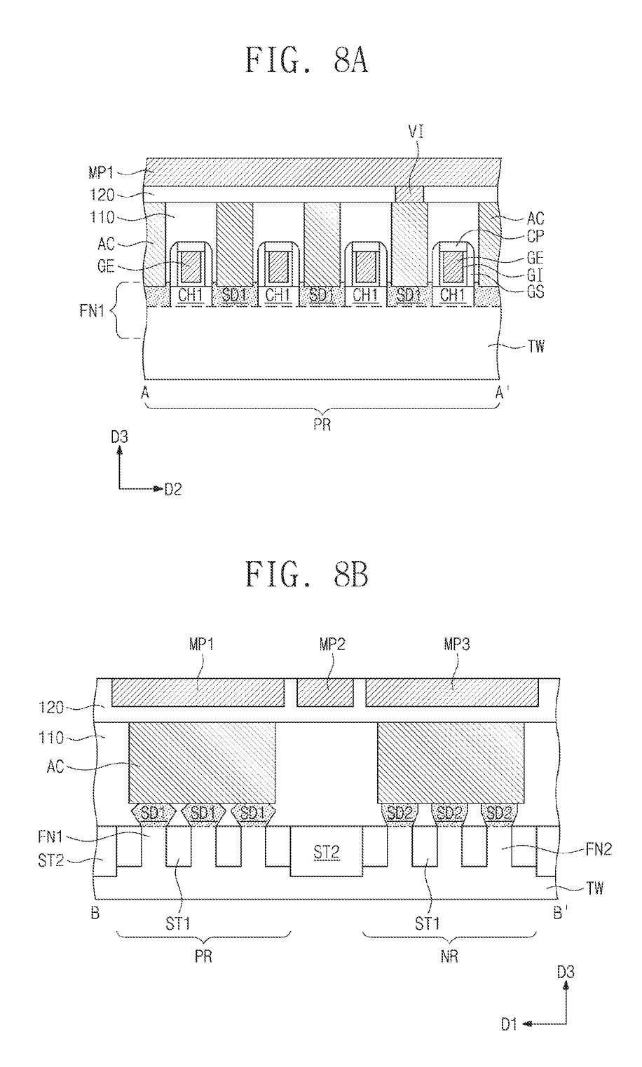

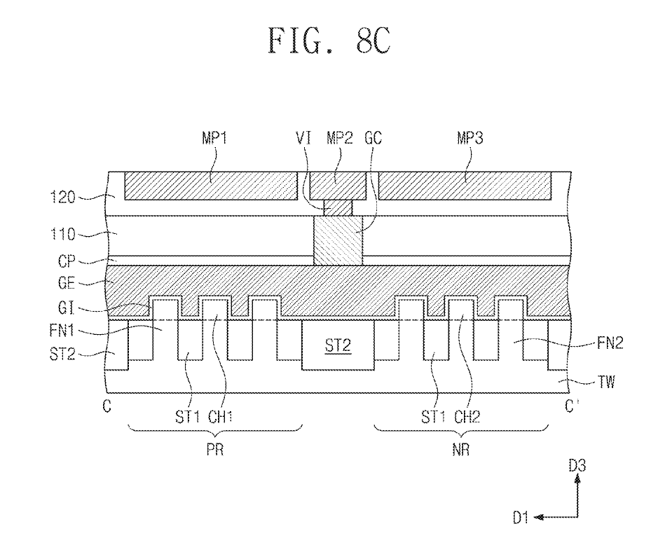

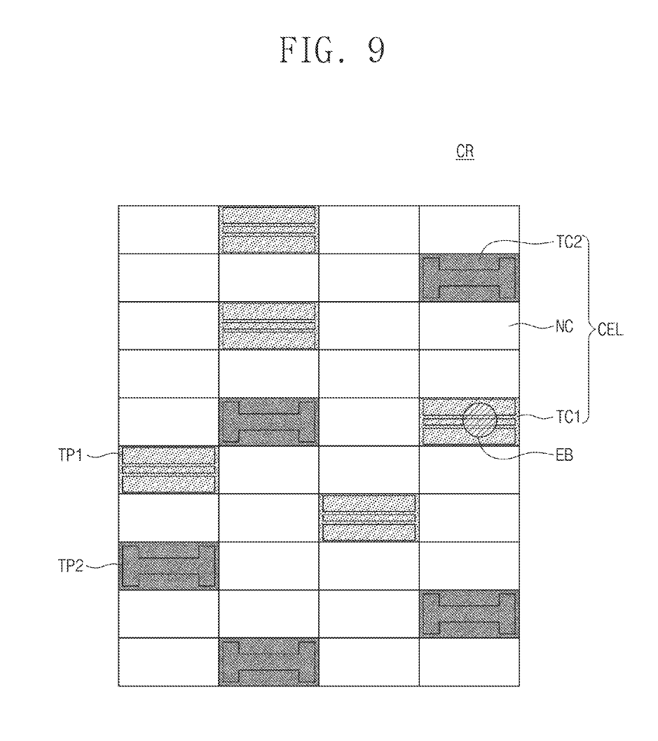

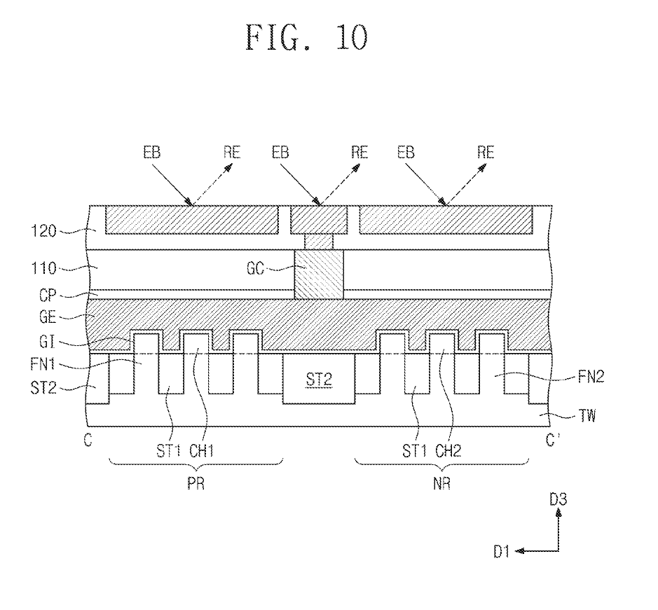

FIG. 1 illustrates a flowchart describing a method of detecting process defects of a semiconductor device, and manufacturing a semiconductor device according to exemplary embodiments of the present inventive concept. FIG. 2 illustrates a plan view showing a wafer on which transistors are formed according to exemplary embodiments of the present inventive concept. FIGS. 3, 6, and 9 illustrate a cell region in one chip of FIG. 2, and show a method of detecting process defects of a semiconductor device. FIG. 4 illustrates an enlarged plan view showing section M of FIG. 3. FIGS. 5A, 5B, and 5C illustrate cross-sectional views respectively taken along lines A-A′, B-B′, and C-C′ of FIG. 4. FIG. 7 illustrates an enlarged plan view showing section M of FIG. 6. FIGS. 8A, 8B, and 8C illustrate cross-sectional views respectively taken along lines A-A′, B-B′, and C-C′ of FIG. 7. FIG. 10 illustrates a simplified cross-sectional view showing an electron beam scanning a first test cell of FIG. 9.

Referring to FIGS. 1 and 2, a method of manufacturing a semiconductor device according to exemplary embodiments of the present inventive concept include detecting process defects of a semiconductor device (S100). A test wafer TW may be used to detect process defects in manufacturing a semiconductor device. For example, a method of detecting process defects of a semiconductor device according to exemplary embodiments includes performing a first process to form transistors on the test wafer TW (S110), forming test patterns on test cells in a cell region of the test wafer TW (S120), and detecting process defects by an electron beam scanning on the test patterns of the test wafer TW (S130). The detected process defects may be inspected to detect process defects in the first process. That is, a method of detecting process defects of a semiconductor device according to exemplary embodiments may be executed such that the detected process defects are inspected to improve processes to manufacture a highly reliable semiconductor device.

The test wafer WF may be utilized to test process defects before manufacturing a semiconductor device that is going to be used as a commercial product. The test wafer TW may include a plurality of chips CI.

Referring to FIGS. 1 to 4 and 5A to 5C, the first process may be performed on the test wafer TW. The first process may be, for example, a front-end-of-line (FEOL) process. Through the first process, transistors may be formed on the test wafer TW (S110). For example, the first process may form a plurality of FEOL components including transistors on the test wafer TW.

Each of the chips CI of the test wafer TW may include at least one cell region CR. The cell region CR according may be a logic cell region where logic transistors are disposed to constitute a logic circuit of a semiconductor device. Accordingly, logic transistors may be formed in the cell region CR.

The cell region CR may include a plurality of cells CEL. Each of the cells CEL may be, for example, a logic cell. The cells CEL may include normal cells NC, first test cells TC1, and second test cells TC2. In exemplary embodiments, the first test cells TC1 may have the same size and transistor arrangement structure as one another, the second test cells TC2 may have the same size and transistor arrangement structure as one another, and the first and second test cells TC1 and TC2 may have different sizes and transistor arrangement structures from each other.

Process defects may occur on the first and second test cells TC1 and TC2 from among the cells CEL of the cell region CR. Cells having a high probability of occurrence of process defects may be predetermined as test cells from among the cells CEL of the cell region CR.

The formation of transistors in the cell region CR of the test wafer TW (e.g., the first process) will be further described in detail with reference to FIGS. 4 and 5A to 5C. Although FIGS. 4 and 5A to 5C show that transistor are formed on the first test cell TC1, exemplary embodiments are not limited thereto. For example, in exemplary embodiments, other cells CEL may also be provided thereon with the same transistors as those formed on the first test cell TC1 through the first process, which will be discussed below.

An upper portion of the test wafer TW may be patterned to form first and second active patterns FN1 and FN2. The test wafer TW may be, for example, a silicon substrate, a germanium substrate, or a silicon-on-insulator (SOI) substrate. The first and second active patterns FN1 and FN2 extend in a second direction D2, as shown in FIG. 4. First device isolation layers ST1 are formed to fill between the first and second active patterns FN1 and FN2, as shown in FIGS. 5B and 5C. Each upper portion of the first and second active patterns FN1 and FN2 has a fin shape that vertically protrudes beyond the first device isolation layers ST1.

A second isolation layer ST2 is formed on the test wafer TW. The second isolation layer ST2 defines a p-channel metal-oxide field-effect transistor (PMOSFET) region PR and an n-channel metal-oxide field-effect transistor (NMOSFET) region NR. The first active patterns FN1 are disposed in the PMOSFET region PR, and the second active patterns FN2 are disposed in the NMOSFET region NR. A shallow trench isolation (STI) process may be used to form the first and second device isolation layers ST1 and ST2. Silicon oxide may be used to form the first and second device isolation layers ST1 and ST2.

Gate electrodes GE are formed to extend in a first direction D1 and to extend across the first and second active patterns FN1 and FN2. Gate dielectric layers GI are formed below the gate electrodes GE. Gate spacers GS are formed on opposite sides of each of the gate electrodes GE. Gate capping layers CP are formed on the gate electrodes GE.

The formation of the gate electrodes GE may include, for example, forming sacrificial patterns that extend across the first and second active patterns FN1 and FN2, forming the gate spacers GS on opposite sides of each of the sacrificial patterns, and replacing the sacrificial patterns with the gate electrodes GE.

The gate electrodes GE may include, for example, one or more of conductive metal nitride (e.g., titanium nitride or tantalum nitride) and metal (e.g., titanium, tantalum, tungsten, copper, or aluminum). The gate dielectric layers GI may include, for example, a high-k dielectric material (e.g., hafnium oxide, lanthanum oxide, or zirconium oxide) whose dielectric constant is greater than that of silicon oxide. The gate spacers GS may include, for example, one or more of SiCN, SiCON, and SiN. The gate capping layers CP may include, for example, one or more of SiON, SiCN, SiCON, and SiN.

First source/drain regions SD1 are formed on upper portions of the first active patterns FN1. Second source/drain regions SD2 are formed on upper portions of the second active patterns FN2. A first channel region CH1 is defined between a pair of the first source/drain regions SD1, and a second channel region CH2 is defined between a pair of the second source/drain regions SD2. The first and second source/drain regions SD1 and SD2 are each formed on opposite sides of each of the gate electrodes GE. The first source/drain regions SD1 may be doped with p-type impurities, and the second source/drain regions SD2 may be doped with n-type impurities.

The first and second source/drain regions SD1 and SD2 may be epitaxial patterns formed by a selective epitaxial growth process. For example, a process may be performed to partially recess the first and second active patterns FN1 and FN2 each provided on opposite sides of each of the gate electrodes GE, and then an epitaxial growth process may be performed on the recessed portions of the first and second active patterns FN1 and FN2.

A first interlayer dielectric layer 110 is formed on a surface (e.g., an entire surface) of the test wafer TW. The first interlayer dielectric layer 110 may be formed of, for example, a silicon oxide layer or a silicon oxynitride layer. Active contacts AC and gate contacts GC are formed in the first interlayer dielectric layer 110. The active contacts AC are formed on the first and second source/drain regions SD1 and SD2. The active contacts AC may have a bar shape extending in the first direction D1. The gate contacts GC are formed on the gate electrodes GE. The gate contacts GC may have a bar shape extending in the second direction D2. The active contacts AC and the gate contacts GC may include at least one metallic material such as, for example, aluminum, copper, tungsten, molybdenum, and/or cobalt. The active contacts AC are coupled (e.g., electrically coupled) to the first and second source/drain regions SD1 and SD2, and the gate contacts GC are coupled (e.g., electrically coupled) to the gate electrodes GE.

Referring to FIGS. 1, 2, 6, 7, and 8A to 8C, a second process may be performed on the test wafer TW after the first process has been performed on the test wafer TW. The second process may be, for example, a process in which test patterns TP1 and TP2 are formed. For example, through the second process, first test patterns TP1 may be formed on the first test cells TC1 of the test wafer TW, and second test patterns TP2 may be formed on the second test cells TC2 of the test wafer TW. In contrast, when the second process is performed, no patterns are formed on the normal cells NC.

The formation of the first test pattern TP1 on the first test cell TC1 (e.g., the second process) will be further described in detail with reference to FIGS. 7 and 8A to 8C. Although FIGS. 7 and 8A to 8C show that the first test pattern TP1 is formed on the first test cell TC1, the second test cell TC2 may also be provided thereon with the second test pattern TP2 through the second process, which will be described below.

A second interlayer dielectric layer 120 is formed on the first interlayer dielectric layer 110 covering the transistors on the test wafer TW. The second interlayer dielectric layer 120 may be formed of, for example, a silicon oxide layer or a silicon oxynitride layer.

The first test pattern TP1 and vias VI are formed in the second interlayer dielectric layer 120. The vias VI are formed between the first test pattern TP1 and the active contacts AC, and between the first test pattern TP1 and the gate contacts GC. The first test pattern TP1 and the vias VI may include, for example, a metallic material (e.g., titanium, tantalum, tungsten, copper, or aluminum). The first test pattern TP1 and the vias VI may include the same metallic material. A damascene process may be employed to form the first test pattern TP1 and the vias VI. For example, when a dual damascene process is used, the first test pattern TP1 and the vias VI may be formed to have a single body.

The first test pattern TP1 and the second test pattern TP2 are electrically connected to the transistors in the cell region CR. In an exemplary embodiment, the second test pattern TP2 has a planar shape different from that of the first test pattern TP1. The first test pattern TP1 includes a first metal pad MP1, a second metal pad MP2, and a third metal pad MP3. The first metal pad MP1 is formed on the PMOSFET region PR, and the third metal pad MP3 is formed on the NMOSFET region NR. The second metal pad MP2 is formed on the gate contacts GC.

The first metal pad MP1 is electrically connected through the via VI and the active contact AC to the first source/drain regions SD1 of the PMOSFET region PR. The third metal pad MP3 is electrically connected through the via VI and the active contact AC to the second source/drain regions SD2 of the NMOSFET region NR. The second metal pad MP2 is electrically connected through the via VI and the gate contact GC to the gate electrodes GE.

The second test pattern TP2 on the second test cell TC2 may be formed to have a different shape from that of the first test pattern TP1.

Referring to FIGS. 1, 2, 9, and 10, an electron beam EB is irradiated onto the test wafer TW that has undergone the second process. A scanning process is performed on electrons emitted from the first and second test patterns TP1 and TP2 in response to the electron beam EB being irradiated onto the first and second test patterns TP1 and TP2 (S130). For example, a method of detecting process defects using the electron beam EB may use an electron beam inspection process including a voltage contrast inspection process.

The electron beam inspection process will be described below.

In exemplary embodiments, an electron beam is irradiated onto a target, and in response, electrons are emitted from the target onto which the electron beam is irradiated. A detector then scans the emitted electrons. The irradiation and the scanning may be performed along a scan path, and the scanned electrons may be displayed as an image. According to exemplary embodiments, the image is brightly displayed when high intensity electrons are emitted, whereas the image is darkly displayed when low intensity electrons are emitted. The image may be analyzed to determine the presence of process defects such as, for example, an electrical short circuit and an electrical open circuit.

The scanning of the first test pattern TP1 on the first test cell TC1 using the electron beam EB will be further described in detail with reference to FIGS. 9 and 10. In exemplary embodiments, the electron beam EB is irradiated onto the first to third metal pads MP1, MP2, and MP3 of the first test cell TC1. An electron RE is emitted from each of the first to third metal pads MP1 to MP3 in response to the electron beam EB being irradiated onto the first to third metal pads MP1, MP2, and MP3. The emitted electron RE may be scanned to determine whether process defects such as, for example, an electrical short circuit or an electrical open circuit are present on the first test cell TC1. The electron beam EB may also be used to scan the second test pattern TP2 on the second test cell TC2.

A highly-reliable inspection result may be obtained from a method of detecting process defects of a semiconductor device and a method of manufacturing a semiconductor device including the same according to exemplary embodiments of the present inventive concept. For example, according to exemplary embodiments, the cell region CR in the test wafer TW may be the same as a cell region of a semiconductor device to be used as a commercial product. The result, obtained from the electron beam inspection performed on the first and second test patterns TP1 and TP2 in the cell region CR of the test wafer TW, may indicate process defects found in commercial semiconductor devices. The first process (e.g., the FEOL process) for forming the cell region may be improved based on the inspection result. As a result, a highly-reliable semiconductor device may be manufactured.

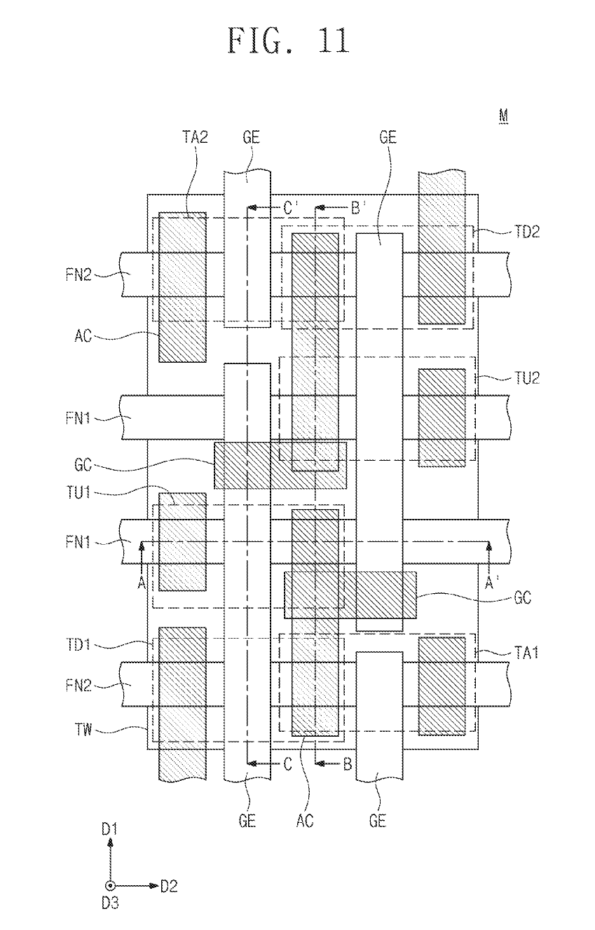

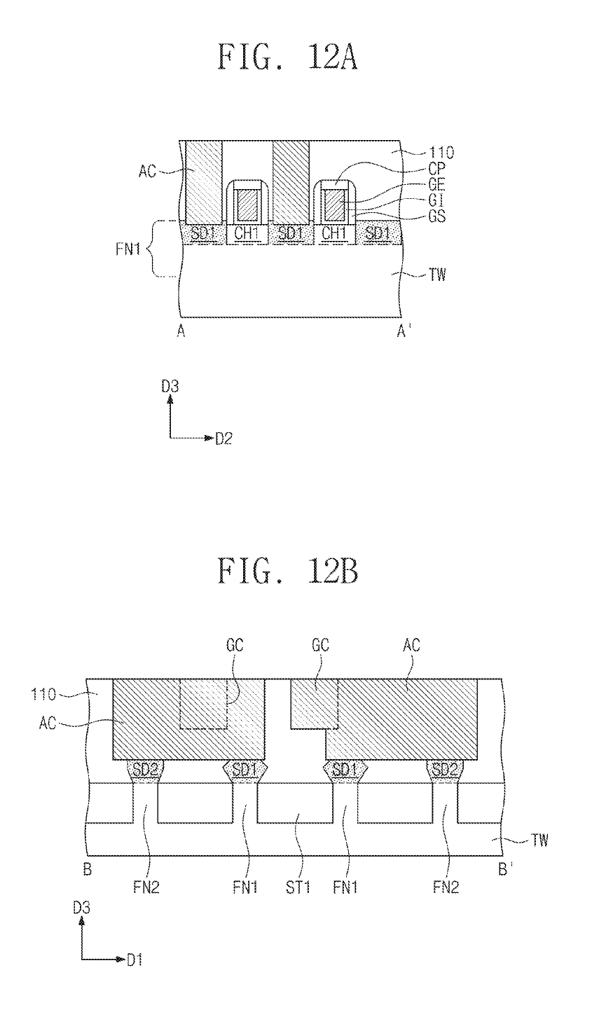

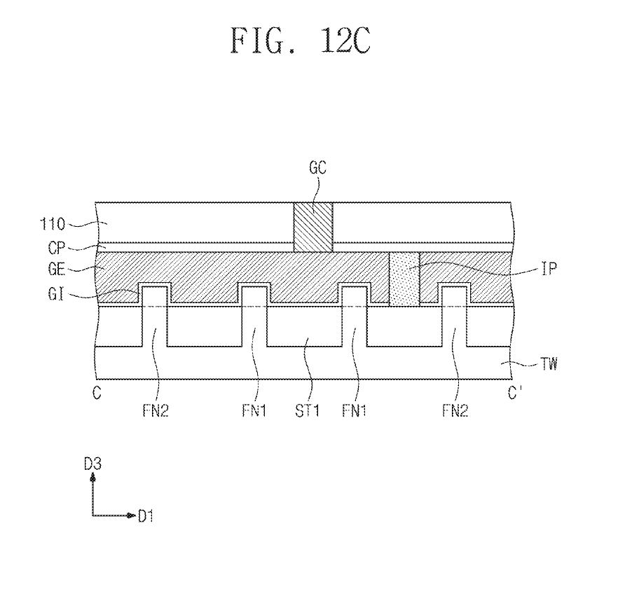

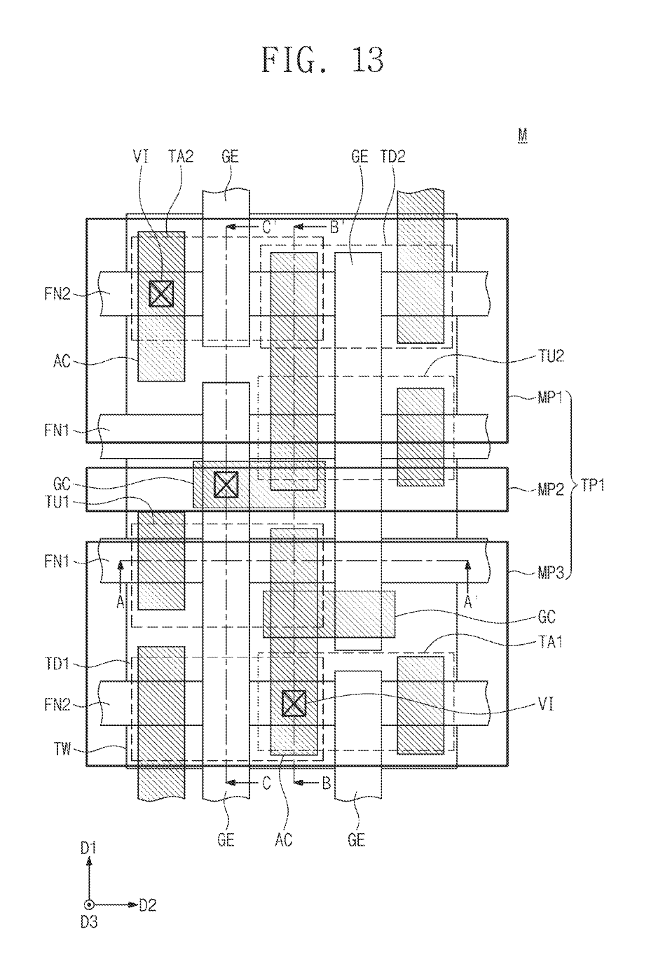

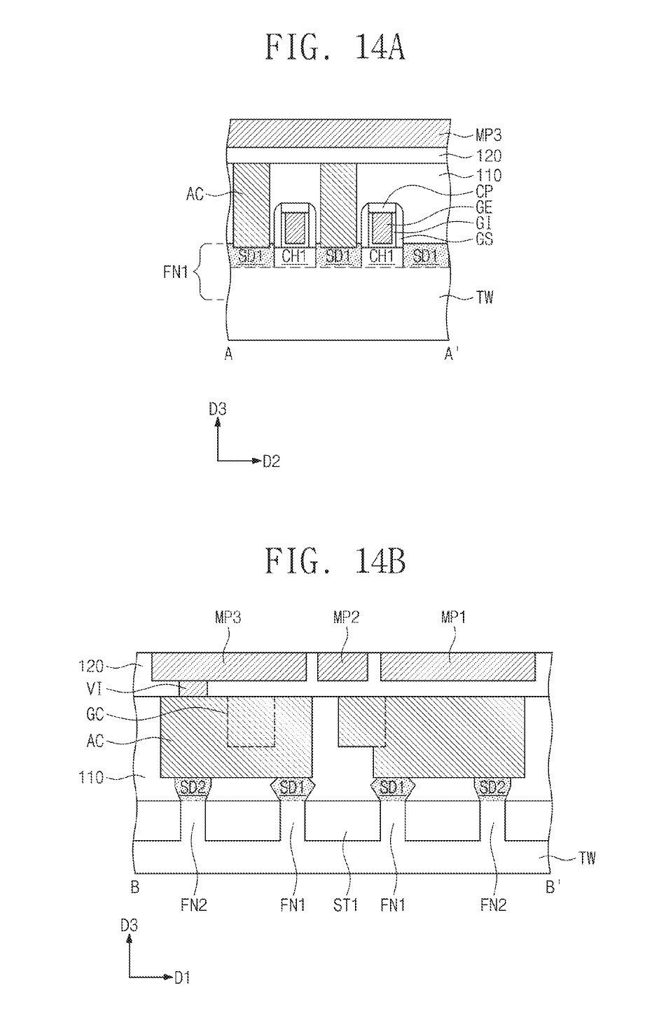

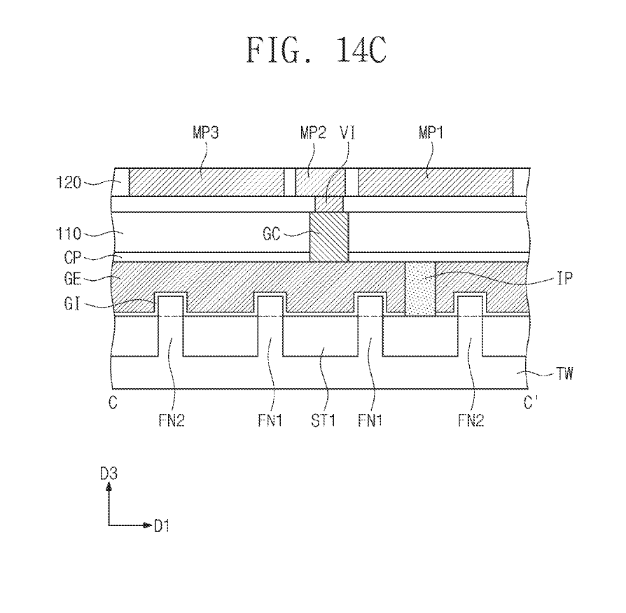

FIGS. 11 and 13 illustrate enlarged plan views respectively showing section M of FIG. 3 and section M of FIG. 7, showing memory cells according to exemplary embodiments of the present inventive concept. FIGS. 12A, 12B, and 12C illustrate cross-sectional views respectively taken along lines A-A′, B-B′, and C-C′ of FIG. 11. FIGS. 14A, 14B, and 14C illustrate cross-sectional views respectively taken along lines A-A′, B-B′, and C-C′ of FIG. 13.

Referring to FIGS. 1, 2, 3, 11, and 12A to 12C, the cell region CR of the test wafer TW according to an exemplary embodiment may be a memory cell region where memory transistors are disposed to store data. Accordingly, memory transistors may be formed in the cell region CR.

The cell region CR includes a plurality of cells CEL. Each of the cells CEL may be, for example, an SRAM cell. The cells CEL may include normal cells NC, first test cells TC1, and second test cells TC2.

The formation of memory transistors in the cell region CR of the test wafer TW (e.g., a first process) will be further described in detail with reference to FIGS. 11 and 12A to 12C. For convenience of explanation, a further detailed description of features already described with reference to FIGS. 4 and 5A to 5C will be omitted herein.

An upper portion of the test wafer TW may be patterned to form first and second active patterns FN1 and FN2. A pair of the first active patterns FN1 is formed between a pair of the second active patterns FN2. First device isolation layers ST1 are formed to fill between the first and second active patterns FN1 and FN2.

Gate electrodes GE are formed to extend in a first direction D1 and to extend across the first and second active patterns FN1 and FN2. An insulating pattern IP is formed between the gate electrodes GE aligned with each other in the first direction D1. Gate dielectric layers GI are formed below the gate electrodes GE. Gate spacers GS are formed on opposite sides of each of the gate electrodes GE. Gate capping layers CP are formed on the gate electrodes GE. First and second source/drain regions SD1 and SD2 are formed on upper portions of the first and second active patterns FN1 and FN2, respectively.

A first interlayer dielectric layer 110 is formed on a surface (e.g., an entire surface) of the test wafer TW. Active contacts AC are formed in the first interlayer dielectric layer 110 and contact the first and second source/drain regions SD1 and SD2. Gate contacts GC are formed in the first interlayer dielectric layer 110 and contact the gate electrodes GE. At least one gate contact GC and at least one active contact AC are emerged to form a single conductive structure.

On the cell CEL of the cell region CR, the first and second active patterns FN1 and FN2 and the gate electrodes GE constitute memory transistors TU1, TD1, TU2, TD2, TA1, and TA2. The memory cell transistors TU1, TD1, TU2, TD2, TA1, and TA2 include a first pull-up transistor TU1, a first pull-down transistor TD1, a second pull-up transistor TU2, a second pull-down transistor TD2, a first access transistor TA1, and a second access transistor TA2. In an exemplary embodiment, the first and second pull-up transistors TU1 and TU2 are PMOS transistors, and the first and second pull-down transistors TD1 and TD2 and the first and second access transistors TA1 and TA2 are NMOS transistors. In an exemplary embodiment, the first pull-up transistor TU1 and the first pull-down transistor TD1 constitute a first inverter, the second pull-up transistor TU2 and the second pull-down transistors TD2 constitute a second inverter, and the first and second inverters are connected to constitute a latch structure.

Referring to FIGS. 1, 2, 6, 13, and 14A to 14C, according to exemplary embodiments, a second process is performed on the test wafer TW on which the memory transistors have been formed by the first process. Through the second process, test patterns may be formed on the test wafer TW (S120).

Referring to FIGS. 13 and 14A to 14C, the second process may be performed in the same manner as that discussed with reference to FIGS. 7 and 8A to 8C, thereby forming vias VI and a first test pattern TP1 on the first test cell TC1 on which the memory transistors are formed. The vias VI may be formed between the first test pattern TP1 and the active contacts AC and between the first test pattern TP1 and the gate contacts GC.

As described above with reference to FIGS. 1, 2, and 9, according to exemplary embodiments, an electron beam EB is irradiated onto the test wafer TW that has undergone the second process. The electron beam EB may be used to detect process defects of the memory cell, as described above.

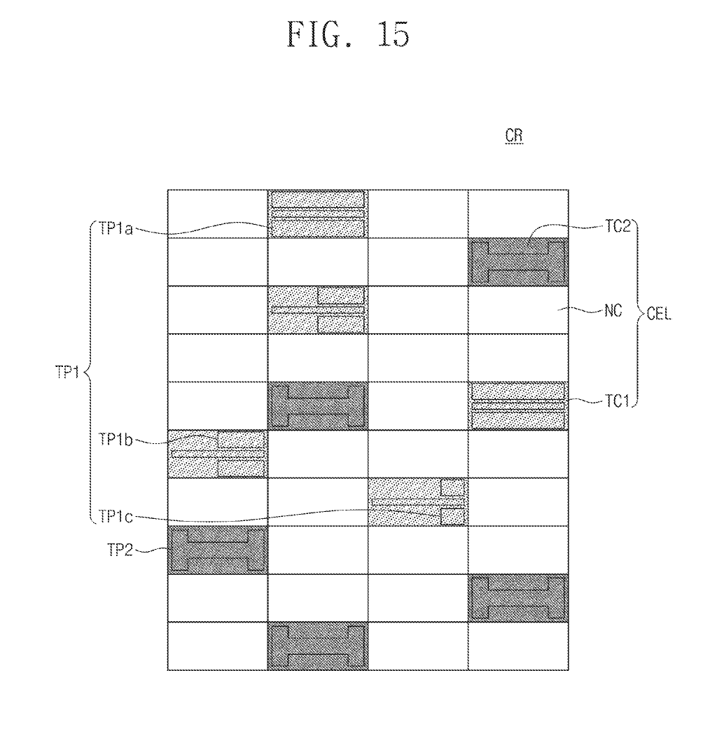

FIG. 15 illustrates a plan view of test patterns formed in a cell region in one chip of FIG. 2, showing a method of detecting process defects of a semiconductor device according to exemplary embodiments of the present inventive concept.

Referring to FIGS. 1, 2, and 15, a method of detecting process defects of a semiconductor device according to an exemplary embodiment includes forming the first and second test patterns TP1 and TP2 in the cell region CR (S120). In contrast to the exemplary embodiment described above with reference to FIG. 6, in the exemplary embodiment described with reference to FIG. 15, the first test patterns TP1 include first sub-test patterns TP1a, second sub-test patterns TP1b, and third sub-test patterns TP1c. The first sub-test pattern TP1a may be formed on at least one of the first test cells TC1, the second sub-test pattern TP1b may be formed on at least another one of the first test cells TC1, and the third sub-test pattern TP1c may be formed on at least another one of the first test cells TC1.

The first to third sub-test patterns TP1a, TP1b, and TP1c may have metal pads having sizes that are different from one another. For example, in an exemplary embodiment, the metal pad of the first sub-test pad TP1a has a size greater than that of the metal pad of the second sub-test pad TP1b, and the size of the metal pad of the second sub-test pad TP1b is greater than that of the metal pad of the third sub-test pad TP1c.

An electron beam scanning process performed on the first sub-test pattern TP1a may take a longer amount of time than that of an electron beam scanning process performed on the third sub-test pattern TP1c. Nevertheless, high accuracy results may be obtained when a scanning result of the first sub-test pattern TP1a is examined to detect process defects, compared to a case in which a scanning result of the third sub-test pattern TP1c is examined. This may be because, for example, the size of the metal pad of the first sub-test pad TP1a is greater than that of the metal pad of the third sub-test pad TP1c.

In an exemplary scenario in which defect detection accuracy is prioritized over reducing the testing time, the scanning may be selectively performed on the first sub-test patterns TP1a. In another exemplary scenario in which reducing the testing time is prioritized over defect detection accuracy, the scanning may be selectively performed on the third sub-test patterns TP1c. In another exemplary scenario in which a compromise is made regarding improving defect detection accuracy and reducing the testing time, the scanning may be selectively performed on the second sub-test patterns TP1b.

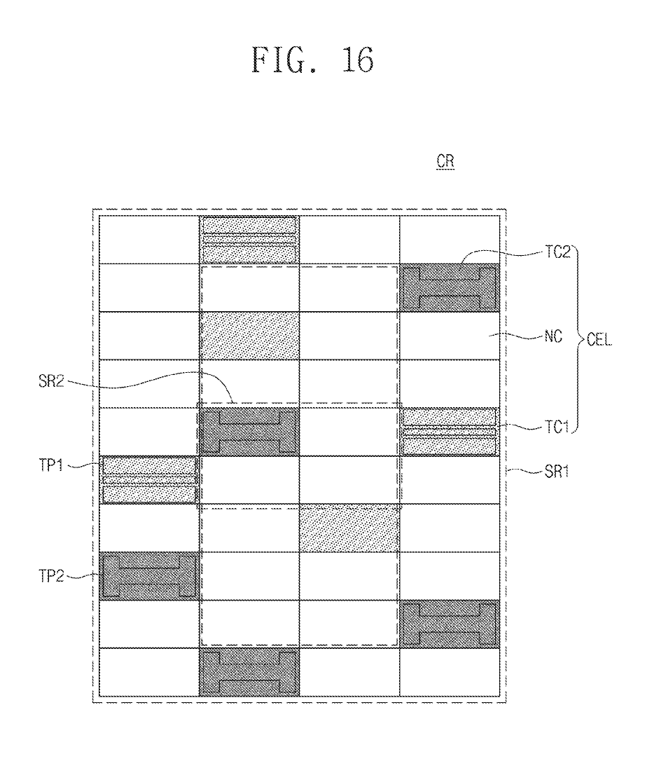

FIG. 16 illustrates a plan view of test patterns formed in a cell region in one chip of FIG. 2, showing a method of detecting process defects on a semiconductor device according to exemplary embodiments of the present inventive concept.

Referring to FIGS. 1, 2, and 16, a method of detecting process defects of a semiconductor device according to an exemplary embodiment includes selectively forming test patterns on a scan region (S120) and scanning the test patterns on the scan region (S130).

According to an exemplary embodiment, a first scan region SR1 and a second scan region SR2 are defined in the cell region CR of the test wafer TW. The first scan region SR1 occupies an edge zone of the cell region CR, and the second scan region SR2 occupies a central zone of the cell region CR.

Detection of process defects of a semiconductor device according to an exemplary embodiment is selectively performed on the first and second scan regions SR1 and SR2. The edge zone of the cell region CR may be an area in which process defects commonly occur as a result of influences of other components adjacent to the cell region CR. The central zone of the cell region CR may indicate an average state of the cell region CR. Accordingly, testing time may be reduced when the detection of process defects is selectively performed on the first scan region SR1 and/or the second scan region SR2 rather than on the entirety of the cell region CR.

According to exemplary embodiments, the first test pattern TP1 is selectively formed on an edge of the cell region CR (e.g., in the edge zone) or in a central zone of the cell region CR. When the first test pattern TP1 is selectively formed on the edge, the first test pattern TP1 is not formed in the central zone. When the first test pattern TP1 is selectively formed in the central zone, the first test pattern TP1 is not formed on the edge. The first test pattern TP1 is selectively scanned based on the location in which the first test pattern TP1 is formed. For example, when the first test pattern TP1 is formed on the edge, scanning is selectively performed on the edge (and not performed in the central zone). Alternatively, when the first test pattern TP1 is formed in the central zone, scanning is selectively performed on the central zone (and not performed on the edge).

In an exemplary embodiment, first and second test patterns TP1 and TP2 are formed on first and second test cells TC1 and TC2 in the first and second scan regions SR1 and SR2, and no test patterns are formed on the first and second test cells TC1 and TC2 provided on regions other than the first and second scan regions SR1 and SR2.

The electron beam EB may be used to scan the first and second test patterns TP1 and TP2 in the first and second scan regions SR1 and SR2. In an exemplary embodiment, the scanning is selectively performed on the first and second scan regions SR1 and SR2. As a result, a scanning time and a defect detection time may be reduced. Alternatively, the scanning may be selectively performed on either the first scan region SR1 or the second scan region SR2.

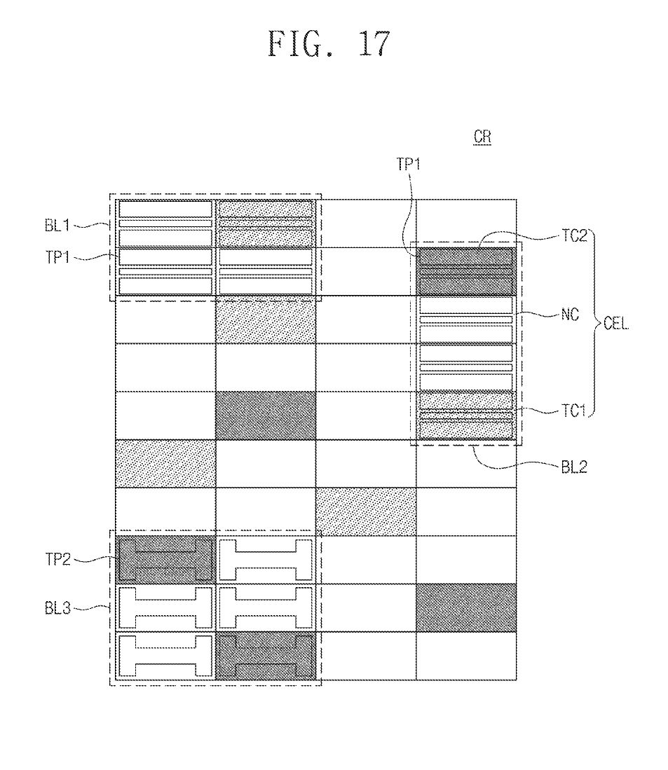

FIG. 17 illustrates a plan view of test patterns formed in a cell region in one chip of FIG. 2, showing a method of detecting process defects on a semiconductor device according to exemplary embodiments of the present inventive concept.

Referring to FIGS. 1, 2, and 17, a method of detecting process defects of a semiconductor device according to an exemplary embodiment includes selectively forming test patterns on a block of the cell region (S120) and scanning the test patterns on the block (S130).

According to an exemplary embodiment, the cell region CR is classified into a plurality of blocks BL1, BL2, and BL3. For example, in an exemplary embodiment, the cell region CR includes a first block BL1, a second block BL2, and a third block BL3. Detection of process defects of a semiconductor device according to an exemplary embodiment is selectively performed on the first to third blocks BL1, BL2, and BL3.

In an exemplary embodiment, the first test pattern TP1 is commonly formed on each of the cells CEL in the first block BL1. The first test pattern TP1 is formed on the first test cell TC1 in the first block BL1, as well as on the normal cell NC in the first block BL1. The first test pattern TP1 is commonly formed on each of the cells CEL in the second block BL2. The first test pattern TP1 is formed on the first test cell TC1 in the second block BL2, as well as on the second test cell TC2 and the normal cell NC in the second block BL2. The second test pattern TP2 is commonly formed on each of the cells CEL in the third block BL3. The second test pattern TP2 is formed on the second test cell TC2 in the third block BL3, as well as on the normal cell NC in the third block BL3. No test patterns are formed on regions other than the first to third blocks BL1, BL2, and BL3.

The electron beam EB may be used to scan the first and second test patterns TP1 and TP2 in the first to third blocks BL1, BL2, and BL3. In exemplary embodiments, the scanning is selectively performed on the first to third blocks BL1, BL2, and BL3. As a result, a scanning time and a defect detection time may be reduced.

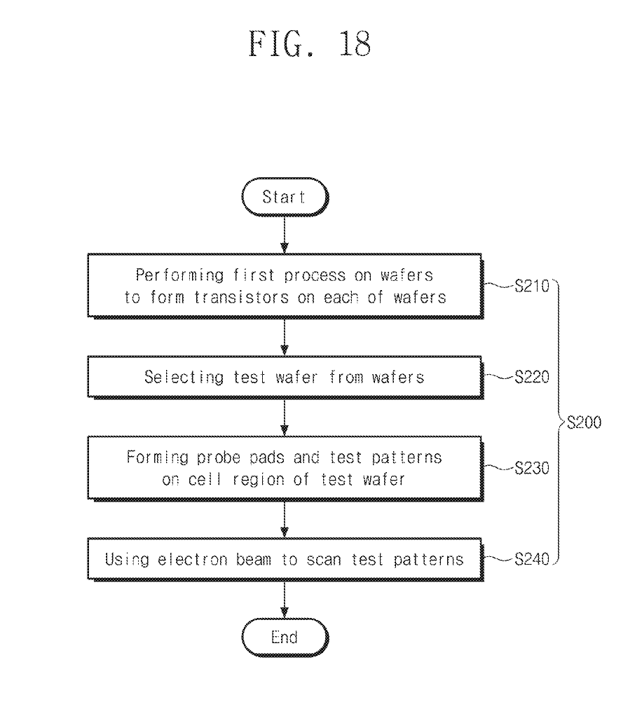

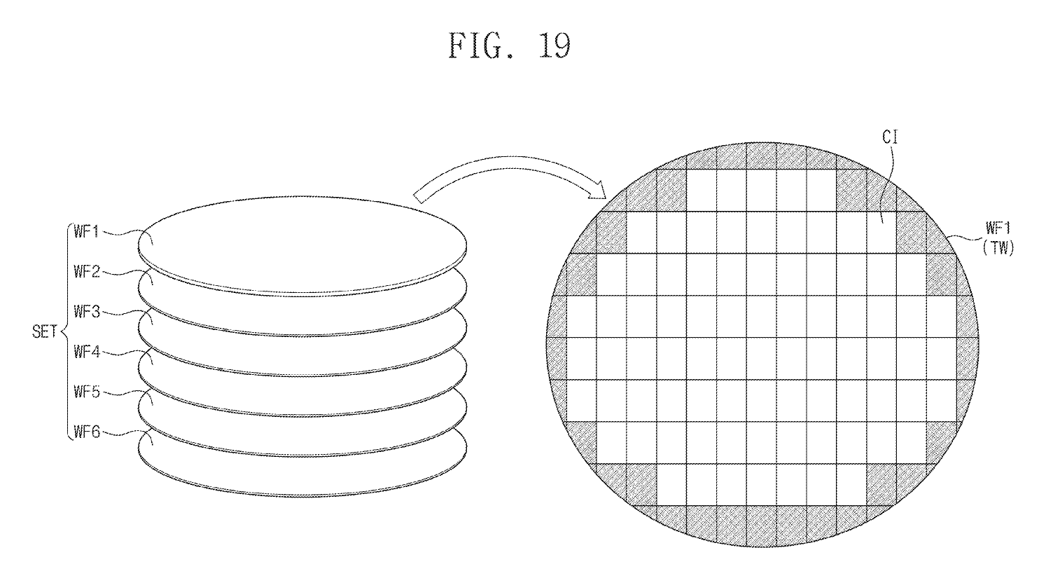

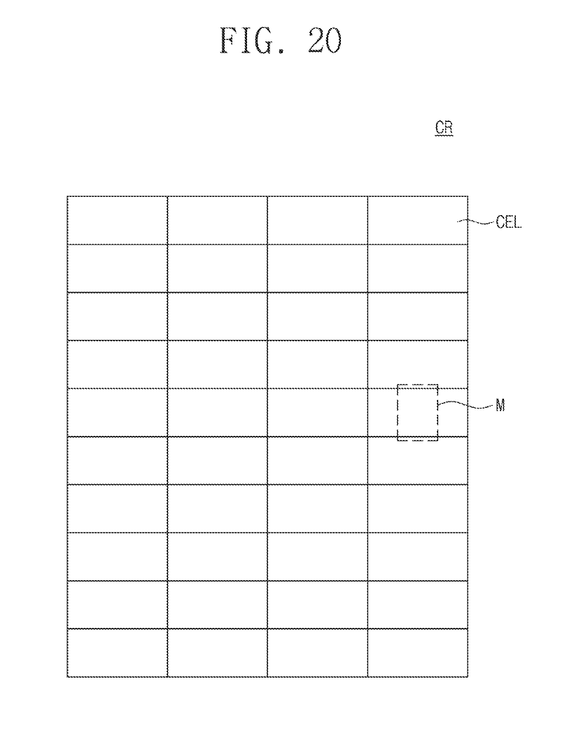

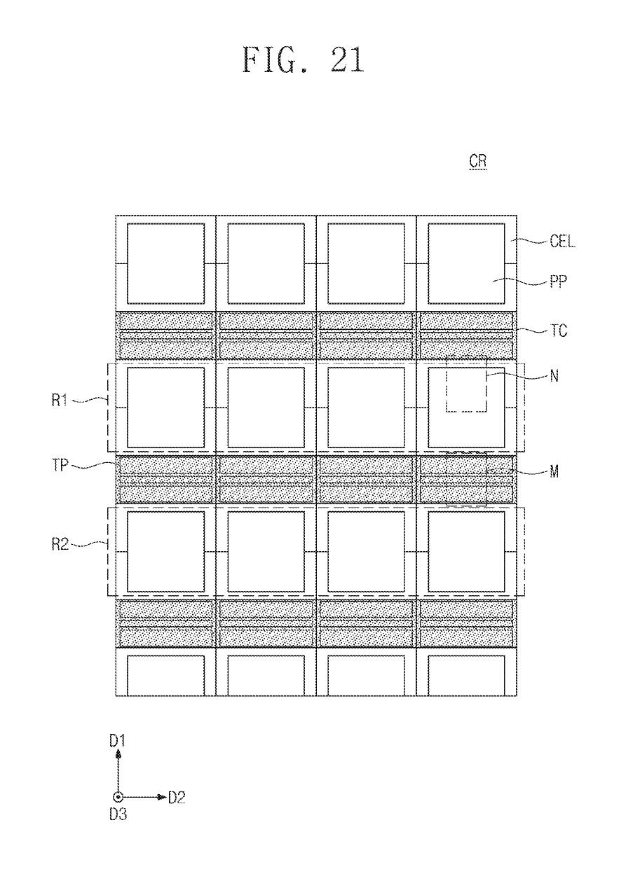

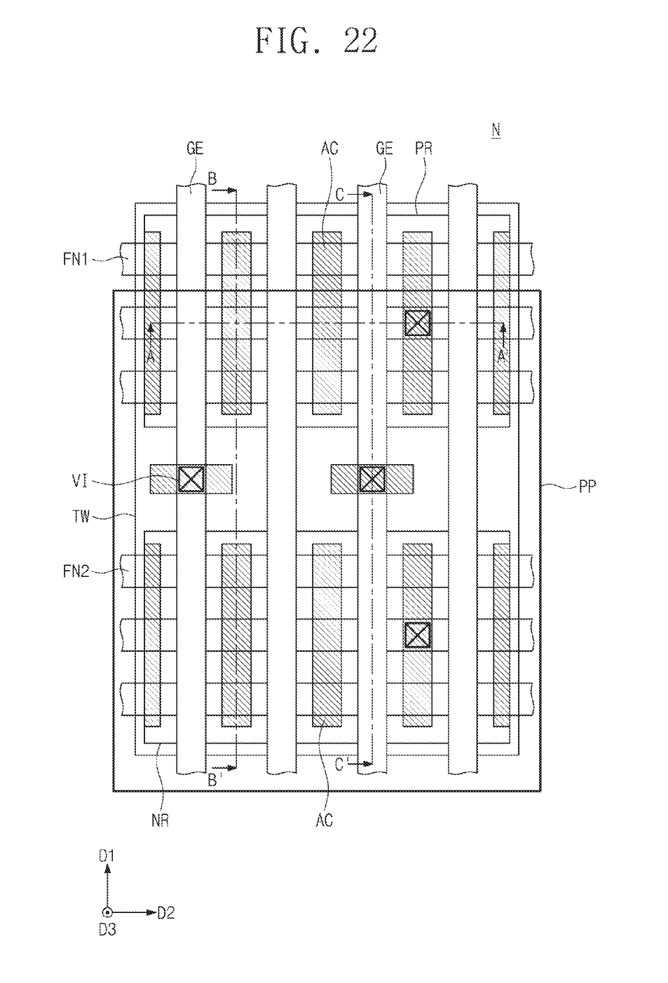

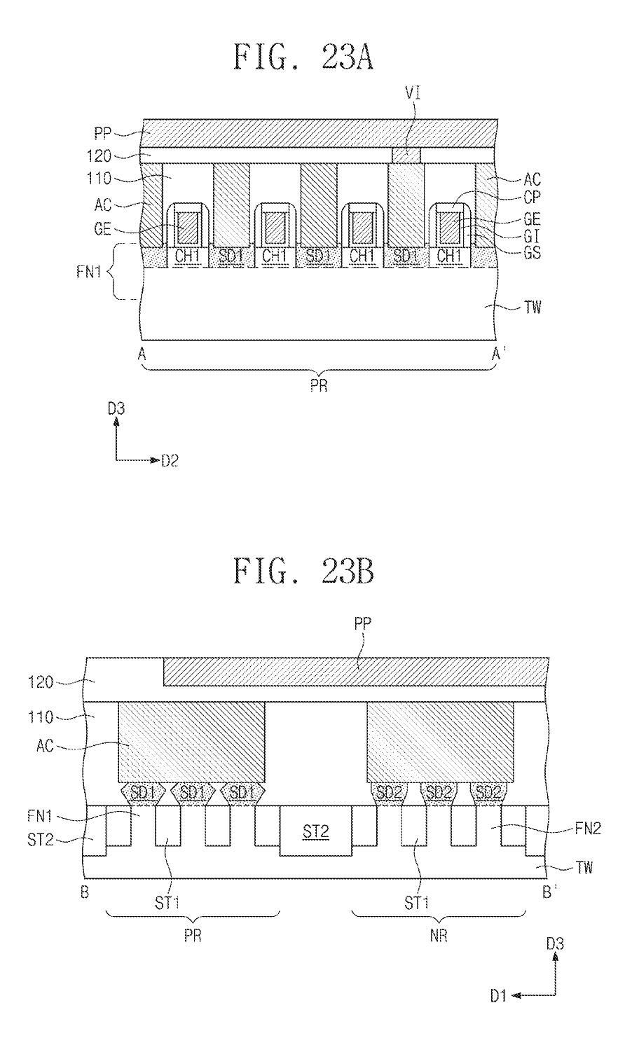

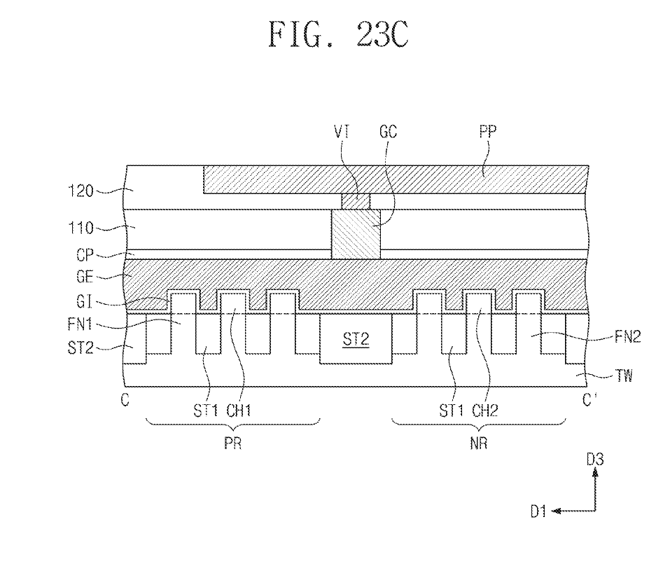

FIG. 18 illustrates a flowchart describing a method of detecting process defects of a semiconductor device, and manufacturing a semiconductor device according to exemplary embodiments of the present inventive concept. FIG. 19 illustrates a plan view showing a test wafer selected from a wafer set that has undergone a first process. FIGS. 20, 21, and 24 illustrate plan views showing a cell region in one chip. FIG. 22 illustrates an enlarged plan view showing section N of FIG. 21. FIGS. 23A, 23B, and 23C are cross-sectional views respectively taken along lines A-A′, B-B′, and C-C′ of FIG. 22.

Referring to FIGS. 18 and 19, according to exemplary embodiments of the present inventive concept, a method of manufacturing a semiconductor device includes detecting process defects of a semiconductor device (S200). A first process may be performed on a wafer set SET to form a semiconductor device to be used as a commercial product. The wafer set SET may include, for example, a plurality of wafers WF1 to WF6. For example, the wafer set SET may include first to sixth wafers WF1 to WF6. The first to sixth wafers WF1 to WF6 may all together go through a semiconductor fabrication facility, and the first process may be commonly performed on the first to sixth wafers WF1 to WF6. As described above, the first process may be, for example, an FEOL process. The first process may form a cell region including transistors on each of the first to sixth wafers WF1 to WF6 (S210). Each of the first to sixth wafers WF1 to WF6 may include a plurality of chips CI to be used as commercial products.

When the first process is complete, one wafer (e.g., the first wafer WF1) may be selected from among the first to sixth wafers WF1 to WF6 (S220). The selected first wafer WF1 may be used as the test wafer TW. A method of detecting process defects according to exemplary embodiments of the inventive concept may be performed on the selected first wafer WF1.

The second to sixth wafers WF2 to WF6 may undergo a subsequent third process, thereby finally manufacturing semiconductor device products. The third process may be, for example, a back-end-of-line (BEOL) process. Through the third process, a plurality of metal layers may be formed on each of the first to sixth wafers WF1 to WF6. For example, according to exemplary embodiments, a first process (e.g., an FEOL process) is performed on a selected wafer (e.g., the test wafer) included in the wafer set SET, and a second process (e.g., a BEOL process) is performed on remaining wafers in the wafer set SET other than the selected test wafer.

Referring to FIGS. 19 and 20, the first process performed on the first to sixth wafers WF1 to WF6 may be substantially the same as that discussed with reference to FIGS. 4 and 5A to 5C. One chip CI of the first wafer WF1 (referred to hereinafter as the test wafer TW) may have a cell region CR corresponding to a logic cell region or a memory cell region formed thereon. The cell region CR may include a plurality of cells CEL. A detailed description and formation of the cell CEL in the cell region CR of the test wafer TW may be substantially the same as the logic cell described above with reference to FIGS. 4 and 5A to 5C, or as the memory cell described above with reference to FIGS. 11 and 12A to 12C.

Referring to FIGS. 18, 21, 22, and 23A to 23C, according to exemplary embodiments, a second process is performed on the test wafer TW that has undergone the first process. The second process may be, for example, a process in which probe pads PP and test pads TP are formed.

Through the second process, the probe pads PP are formed on the cells CL of the test wafer TW (S230). For example, each of the probe pads PP may be formed on two cells CEL. The probe pads PP are arranged along a second direction D2. Some of the probe pads PP (e.g., a first group) are arranged in the second direction D2 to constitute a first row R1, and other probe pads PP (a second group) are arranged in the second direction D2 to constitute a second row R2. The first and second rows R1 and R2 are spaced apart from each other in a first direction D1.

The test pads TP are formed on the cells CEL between the first row R1 of the probe pads PP and the second row R2 of the probe pads PP (S230). In this context, test cells TC refer to the cells CEL between the first row R1 of the probe pads PP and the second row R2 of the probe pads PP. The test cells TC between the first row R1 of the probe pads PP and the second row R2 of the probe pads PP are arranged in the second direction D2. The formation of the test patterns TP on the test cells TC may be substantially the same as that discussed above with reference to FIGS. 7 and 8A to 8C.

The formation of the probe pads PP on the cells CEL will be further described in detail with reference to FIGS. 22 and 23A to 23C. In exemplary embodiments, a second interlayer dielectric layer 120 is formed on a first interlayer dielectric layer 110 covering transistors on the test wafer TW. The probe pad PP and vias VI are formed in the second interlayer dielectric layer 120. The vias VI are formed between the probe pad PP and an active contact AC, and between the probe pad PP and a gate contact GC. The probe pad PP and the vias VI may be formed simultaneously with the test patterns TP and the vias VI on the test cells TC. For example, the probe pad PP and the test patterns TP may include the same metallic material.

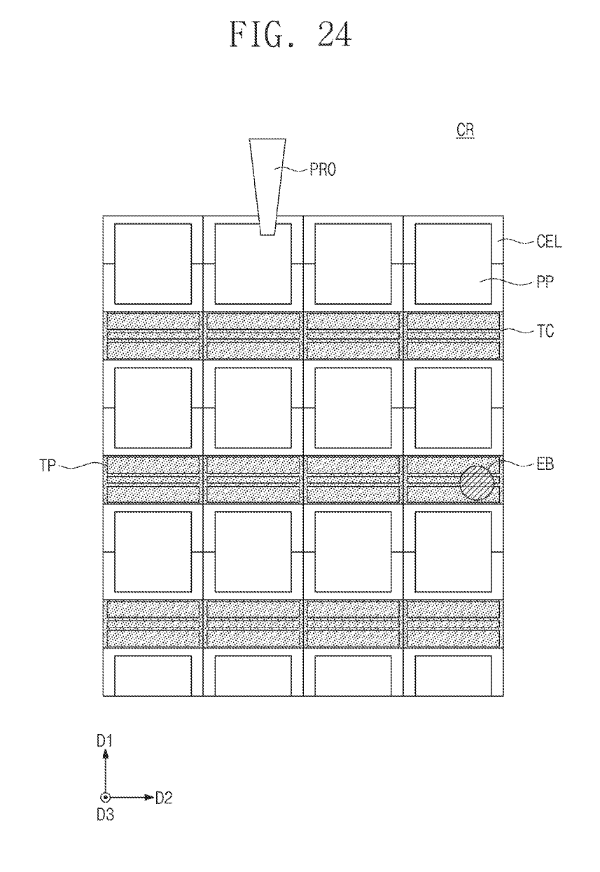

Referring to FIG. 24, in an exemplary embodiment, an electron beam EB is irradiated onto the test wafer TW that has undergone the second process. A scanning process is performed on electrons emitted by the electron beam EB from the test patterns TP (S240). In exemplary embodiments, the scanning process may be performed along the second direction D2 in which the test cells TC are arranged. A method of detecting process defects of a semiconductor device according to exemplary embodiments is selectively performed on the test cells TC. As a result, a scanning time and a defect detection time may be reduced. In addition, a probe PRO may contact the probe pads PP. The probe PRO may inspect an electrical connection between the transistors on the test wafers TW.

In a method of detecting process defects of a semiconductor device and a method of manufacturing a semiconductor including the same according to exemplary embodiments of the inventive concept, one of commercially available wafers may be used as the test wafer TW. Thus, a cell region (e.g., a cell region of the first wafer WF1) in the test wafer TW may be the same as a cell region (e.g., a cell region of each of the second to sixth wafers WF2 to WF6) of a semiconductor device to be used as a commercial product. An inspection result obtained by performing a method according to the exemplary embodiments described herein may include an indication of process defects included in a semiconductor device to be used as a commercial product. The first process (e.g., the FEOL process) for forming the cell region may be improved based on the inspection result, and thereby, a highly-reliable semiconductor device may be manufactured.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

1. A method of manufacturing a semiconductor device, comprising:
forming a plurality of transistors in a cell region of a test wafer;
forming a first test pattern on a first test cell in the cell region of the test wafer, wherein the first test pattern is electrically connected to the transistors; and
scanning the first test pattern using an electron beam,
wherein forming the transistors in the cell region comprises:
forming a plurality of active patterns by patterning an upper portion of the test wafer;
forming a plurality of source/drain regions on the active patterns;
forming a plurality of gate electrodes extending across the active patterns;
forming a plurality of active contacts coupled to the source/drain regions; and
forming a plurality of gate contacts coupled to the gate electrodes.

2. The method of claim 1,
wherein the first test pattern is selectively formed on an edge of the cell region or in a central zone of the cell region,
wherein the scanning is selectively performed on the edge when the first test pattern is formed on the edge, or on the central zone when the first test pattern is formed in the central zone.

3. The method of claim 1, further comprising:
forming a second test pattern on a second test cell in the cell region of the test wafer, wherein the second test pattern is electrically connected to the transistors; and
scanning the second test pattern using the electron beam, wherein the second test pattern has a planar shape different from that of the first test pattern.

4. The method of claim 1,
wherein the first test cell is one of a plurality of first test cells in the cell region,
wherein forming the first test pattern comprises:
forming a first sub-test pattern on at least one of the first test cells; and
forming a second sub-test pattern on at least another one of the first test cells,
wherein the first sub-test pattern has a size different from that of the second sub-test pattern.

5. The method of claim 4, wherein the scanning is selectively performed on the first sub-test pattern or on the second sub-test pattern.

6. The method of claim 1, wherein forming the transistors on the test wafer comprises:
forming transistors on each of a plurality of wafers included in a wafer set by performing a first process on the wafer set;
selecting at least one of the wafers included in the wafer set as the test wafer; and
forming a plurality of metal layers on each of remaining wafers in the wafer set other than the selected wafer by performing a second process on the remaining wafers.

7. The method of claim 6, wherein the first process is a front-end-of-line (FEOL) process, and the second process is a back-end-of-line (BEOL) process.

8. The method of claim 1, wherein the cell region is a logic cell region, and the transistors are logic transistors.

9. The method of claim 1,
wherein the cell region is a memory cell region, the first test cell comprises a plurality of memory transistors, and the memory transistors comprise:
first and second pull-up transistors;
first and second pull-down transistors; and
first and second access transistors.

10. The method of claim 1, wherein forming the first test pattern comprises:
forming a first metal pad electrically connected to at least one of the active contacts; and
forming a second metal pad electrically connected to at least one of the gate contacts.

11. A method of manufacturing a semiconductor device, comprising:
performing an electron beam inspection process on a cell region of a test wafer,
wherein the cell region of the test wafer comprises:
a plurality of first active patterns;
a plurality of second active patterns;
a device isolation layer defining the first and second active patterns, wherein upper portions of the first and second active patterns vertically protrude beyond the device isolation layer;
a plurality of gate electrodes extending across the first and second active patterns; and
a plurality of test patterns electrically connected to at least one of the first and second active patterns and the gate electrodes,
wherein the first active patterns and the gate electrodes constitute a plurality of p-channel metal-oxide field-effect (PMOS) transistors, and
the second active patterns and the gate electrodes constitute a plurality of n-channel metal-oxide field-effect (NMOS) transistors.

12-13. (canceled)

14. The method of claim 11,
wherein the test patterns are selectively formed on an edge of the cell region or in a central zone of the cell region,
wherein the electron beam inspection process is selectively performed on the edge when the test patterns are formed on the edge, or on the central zone when the test patterns are formed in the central zone.

15. The method of claim 11,
wherein the cell region of the test wafer comprises a first test cell and a second test cell,
wherein the second test cell has a transistor arrangement structure different from that of the first test cell,
wherein the test patterns comprise:
a first test pattern on the first test cell; and
a second test pattern on the second test cell, wherein the second test pattern has a planar shape different from that of the first test pattern.

16. The method of claim 11,
wherein the cell region of the test wafer comprises first test cells,
wherein the test patterns comprise:
a first sub-test pattern on at least one of the first test cells; and
a second sub-test pattern on at least another one of the first test cells, wherein the first sub-test pattern has a size different from that of the second sub-test pattern.

17. (canceled)

18. The method of claim 11, further comprising:
forming transistors on each of a plurality of wafers included in a wafer set by performing a first process on the wafer set;
selecting at least one of the wafers included in the wafer set as the test wafer; and
forming a plurality of metal layers on each of remaining wafers in the wafer set other than the selected wafer by performing a second process on the remaining wafers.

19. (canceled)

20. The method of claim 11, wherein the cell region of the test wafer further comprises:
a plurality of probe pads electrically connected to at least one of the first and second active patterns and the gate electrodes,
wherein a first group of the probe pads is arranged in a first direction and forms a first row, a second group of the probe pads is arranged in the first direction and forms a second row, and the test patterns are interposed between the first row and the second row.

21. The method of claim 11, wherein the test patterns comprise:
a first metal pad electrically connected to at least one of the first and second active patterns; and
a second metal pad electrically connected to at least one of the gate electrodes.

22-25. (canceled)

26. A method of manufacturing a semiconductor device, comprising:
forming a plurality of first active patterns in a cell region of a test wafer;
forming a plurality of second active patterns in the cell region;
forming a device isolation layer defining the first and second active patterns, wherein upper portions of the first and second active patterns vertically protrude beyond the device isolation layer;
forming a plurality of gate electrodes extending across the first and second active patterns;
forming a plurality of test patterns electrically connected to at least one of the first and second active patterns and the gate electrodes,
wherein the first active patterns and the gate electrodes constitute a plurality of p-channel metal-oxide field-effect (PMOS) transistors, and the second active patterns and the gate electrodes constitute a plurality of n-channel metal-oxide field-effect (NMOS) transistors;
irradiating an electron beam onto the test patterns; and
detecting at least one process defect by scanning electrons emitted from the test patterns in response to irradiating the electron beam onto the test patterns.

27. The method of claim 26, wherein the cell region is a logic cell region, and the PMOS and NMOS transistors are logic transistors.

28. The method of claim 26,
wherein the cell region is a memory cell region, the PMOS transistors comprise first and second pull-up transistors, and the NMOS transistors comprise first and second pull-down transistors and first and second access transistors.
